(19) United States
(12) Patent Application Publication
(10) Pub. No.: US 2024/0337491 A1
(43) Pub. Date: Oct. 10, 2024

(54) RESONANT SENSOR SYSTEM AND METHOD FOR OPERATING A RESONANT SENSOR SYSTEM

(71) Applicant: Robert Bosch GmbH, Stuttgart (DE)

(72) Inventor: Antonios Nikas, Muenchen (DE)

(21) Appl. No.: 18/616,295

(22) Filed: Mar. 26, 2024

(30) Foreign Application Priority Data
Apr. 4, 2023 (DE) 102023203103.5

(51) Int. Cl. G01C 19/5755; B81B 7/00; G01P 15/097

(52) U.S. Cl. CPC G01C 19/5755; B81B 7/008; G01P 15/097; B81B 2201/0242

(57) ABSTRACT

A resonant sensor system and a method for operating the resonant sensor system. The resonant sensor system includes: a drive circuit configured to generate an analog drive signal to drive an oscillatable seismic element of the MEMS gyroscope; a detection circuit coupled to the drive circuit and the oscillatable seismic element, wherein the detection circuit is configured to detect an analog signal from a motion of the oscillatable seismic element, wherein the analog signal includes an analog rotation-rate signal component and an analog quadrature signal component; and a digital processing arrangement having at least one digital-to-analog converter and a further digital-to-analog converter.

### FIELD

The present invention relates to a resonant sensor system.

### BACKGROUND INFORMATION

Resonant sensor systems, such as sensor systems having an MEMS gyroscope, also have an error/interference signal, the quadrature signal, in addition to their drive and rotation-rate signals, due to misalignments. Because this signal is in phase with the drive signal, in theory it has a phase position that differs by 90° with respect to the rotation-rate signal. Furthermore, the quadrature signal makes a contribution that is in some cases several times larger than the actual rotation-rate signal and therefore dominates its dynamic range; it therefore represents a component that can be optionally compensated for in the overall measured analog signal. The challenge thus arises to compensate for the quadrature signal component in the obtained analog signal as efficiently as possible and to ensure a low level of compensation effort.

Techniques for compensating for the quadrature signal component are widespread and (in some cases) improve the power consumption of the detection circuit (analogous to the front end). A preferred compensation technique is, inter alia, electronic compensation by charge compensation to eliminate the error in or at the input of detection circuits with open control loops. In theory, such a charge compensation can be continuously readjusted when the control loop is open (open loop), but in practice this often results in phase shifts in the detection circuit. However, phase precision and stability are required for further digital compensation to reduce a zero rate error.

### SUMMARY

It is an object of the present invention to provide a resonant sensor system, in particular a sensor system with an MEMS gyroscope, with which it is possible, on the one hand, to effect efficient compensation of a quadrature signal component of an analog signal in a detection circuit and, on the other hand, to keep the phase position of the analog signal constant for subsequent processing.

The resonant sensor system according to the present invention (which is based on the oscillation of a seismic element), in particular the MEMS gyroscope, may have an advantage over the related art that, on the one hand, in the detection circuit, the quadrature signal component of the analog signal can be compensated for by means of compensation during the operation of the sensor (and also a drift of such a compensation occurring during the operation of the sensor) and nevertheless the change in the phase position of the signal thus triggered can also be compensated for. Thus, in combination with the digital processing arrangement, (quasi) continuous compensation can be ensured and the error occurring due to the analog quadrature signal component can be effectively limited over the entire lifetime of the sensor system. Furthermore, the power, linearity and noise of the detection circuit (analogous to the front end) can therefore be efficiently improved and thus allow efficient zero rate offset compensation.

Because the analog quadrature signal component can be many times larger than the analog rotation-rate signal component, according to an example embodiment of the present invention, the amplification range of an interface amplifier, which is in particular coupled to the detection circuit, can be increased by a previously performed compensation of the quadrature signal component, and thus the dynamic range of the rotation-rate signal component can be used effectively. According to the an example embodiment of the present invention, it is thus efficiently possible to compensate for the phase position of the analog signal and in particular of the analog quadrature signal component for as far as possible in the detection circuit, in particular in order to efficiently utilize the amplification range of the coupled interface amplifier.

Advantageous embodiments and developments of the present invention are disclosed herein.

According to an advantageous example embodiment of the present invention, the digital-to-analog converter comprises a first digital-to-analog converter and a second digital-to-analog converter,
wherein the compensation circuit comprises a first compensation circuit and a second compensation circuit,
wherein the first compensation circuit is coupled to the detection circuit and is configured to detect a main absolute value component of the quadrature signal component and to apply a first digital signal to the first digital-to-analog converter to at least partially compensate for the quadrature signal component, wherein the first digital-to-analog converter converts the first digital signal to a first analog signal to compensate for the main absolute value component of the quadrature signal component,
wherein the second compensation circuit is coupled to the detection circuit and configured to detect a further component of the quadrature signal component and to apply a second digital signal to the second digital-to-analog converter to further compensate for the quadrature signal component, wherein the second digital-to-analog converter converts the second digital signal to a second analog signal to further compensate for the quadrature signal component,
wherein the further compensation circuit is configured to receive the second digital signal from the second compensation circuit and to apply the further digital signal to the further digital-to-analog converter to carry out a phase position correction of the phase position of the analog signal by the further digital-to-analog converter, thereby causing at least the phase position of the second analog signal to be inverted. Advantageously, a compensation of the quadrature signal component that is as effective and efficient as possible is thus achieved.

According to an advantageous example embodiment of the present invention, the first digital-to-analog converter has a significantly larger value range that can be covered or represented than the second and the further digital-to-analog converters, in particular a value range that can be covered or represented that is twice as large, particularly preferably a value range that can be covered or represented that is four times as large.

Due to the considerably larger value range or dynamic range of the first digital-to-analog converter that can be covered or represented, it is advantageously possible according to the present invention to represent a larger signal or value range of the analog signal and to compensate for at least the largest part of the quadrature signal component in terms of absolute value. Advantageously, a considerable part (or the main absolute value component) of the analog quadrature signal component can thus be compensated for by the first compensation circuit. Due to the considerably smaller value range of the second and further digital-to-analog converter that can be covered or represented, a more accurate compensation with respect to the remaining quadrature effect (i.e., after the main absolute value component of the quadrature signal component has already been compensated for by means of the first digital-to-analog converter) can be carried out by means of the second compensation circuit and the further compensation circuit with the same number of bits of the digital-to-analog conversion.

According to an advantageous example embodiment of the present invention, the further digital-to-analog converter comprises a structure consisting of a plurality of coupled capacitive units such that the error introduced by the second digital-to-analog converter or by the second analog signal to further compensate for the quadrature signal component can be compensated for in a simple manner with respect to the phase position of the signal. It is thus preferably possible to operate the sensor system efficiently.

According to an advantageous example embodiment of the present invention, the detection circuit is coupled to an interface amplifier. This can thus advantageously be used efficiently because the analog signal that is compensated for is fed to the interface amplifier and the amplification range is thus optimally utilized.

According to an advantageous example embodiment of the present invention, the further digital-to-analog converter is coupled to an analog amplifier, wherein an amplification of up to twenty times, in particular up to ten times, in particular up to five times, preferably in particular up to two times, is preferably carried out. It is thus advantageously possible to operate the sensor system efficiently and to achieve a preferably precisely tuned amplification of the analog signal.

A further object of the present invention is a method for operating a sensor system with an MEMS gyroscope according to the present invention.

The method according to the present invention for operating a resonant sensor system, in particular for operating a sensor system with an MEMS gyroscope, proves to be advantageous over the related art in that the analog quadrature signal component is compensated for (in the compensation step) on the one hand and on the other hand the change in the phase position of the (entire) analog signal additionally triggered by this compensation is counteracted. This combinatorial compensation is achieved particularly effectively and efficiently by the supporting effect of a digital processing arrangement. The quadrature signal component to be compensated for and a phase position correction value for compensating for the phase position of the analog signal can thus be ascertained during the production and calibration or the compensation of the sensor system. In addition, this results in particular in a lower level of compensation effort.

According to an advantageous example embodiment of the present invention, the digital-to-analog converter comprises a first digital-to-analog converter and a second digital-to-analog converter, wherein the compensation circuit comprises a first compensation circuit and a second compensation circuit, wherein the first, second, and the further compensation circuit are each coupled to the detection circuit, wherein:
in a first method step, the first compensation circuit detects a main absolute value component of the quadrature signal component and applies a first digital signal to the first digital-to-analog converter to at least partially compensate for the quadrature signal component, wherein the first digital-to-analog converter converts the first digital signal to a first analog signal to compensate for the main absolute value component of the quadrature signal component,
in a second method step, the compensation step is carried out in such a way that the second compensation circuit, in addition to the main absolute value component of the quadrature signal component, detects a further component of the quadrature signal component and applies a second digital signal to the second digital-to-analog converter to further compensate for the quadrature signal component, wherein the second digital-to-analog converter converts the second digital signal to a second analog signal to further compensate for the quadrature signal component and
   the further compensation circuit receives the second digital signal from the second compensation circuit and applies the further digital signal to the further digital-to-analog converter to carry out the phase position correction of the phase position of the analog signal by the further digital-to-analog converter, thereby causing at least the phase position of the second analog signal to be inverted.

In detail, according to an example embodiment of the present invention, the main absolute value proportion of the quadrature signal component (in the first method step), the further component of the quadrature signal component (not compensated for by the compensation of the main absolute value component) and the change in the phase position of the (entire) analog signal, which is additionally triggered by this compensation (in the second method step), are compensated for by means of the first compensation circuit, the second compensation circuit, and the further compensation circuit. Specifically, the first compensation circuit applies the first digital signal to the first digital-to-analog converter, the second compensation circuit applies the second digital signal to the second digital-to-analog converter, and the further compensation circuit applies the further digital signal to the further digital-to-analog converter. The first analog signal converted by the first digital-to-analog converter compensates for the main absolute value component of the quadrature signal component (in the first method step), the second analog signal converted by the second digital-to-analog converter compensates for the further component of the quadrature signal component (not compensated for by the compensation of the main absolute value component), and the further analog signal converted by the further digital-to-analog converter compensates for the change in the phase position of the (entire) analog signal additionally triggered by this compensation (in the second method step). During the production and calibration of the sensor system, the first digital signal, the second digital signal, and the further digital signal are ascertained in the course of the (as complete as possible) compensation of the quadrature signal component of the analog signal. The second digital signal (hereinafter also designated “trim code 0”) and the further digital signal (hereinafter also designated “trim code 0”) are assigned to the further component of the quadrature signal component and the phase position correction value.

During operation, a deviation (or a drift or signal drift) from the phase position correction value (in terms of time or due to a temperature influence) can be (quasi) continuously monitored and readjusted. Specifically, the first compensation circuit (permanently) applies the first digital signal (hereinafter also designated “trim code c”) to the first digital-to-analog converter, while the further component of the quadrature signal component and the phase position correction value are (quasi) continuously monitored and readjusted by means of a second readjusted digital signal (hereinafter also designated “trim code x”) by the second compensation circuit and a further readjusted digital signal (hereinafter also designated “trim code x”) by the further compensation circuit; consequently, the second method step is preferably carried out not only during the compensation at the end of the production process, but also during the further operation of the sensor arrangement, at least if a renewed need for compensation was determined by corresponding measurements. Both during production and calibration and during operation of the sensor system, the second and further digital signal or the second readjusted and further digital signal are selected such that the further analog signal causes at least one inversion of the phase position of the second analog signal.

Furthermore, a (quasi) continuous compensation of the analog quadrature signal component or of the error associated therewith over the lifetime of the sensor system is thus ensured. As a further effect, the power, linearity and noise of the detection circuit (analogous to the front end) can be improved and an efficient zero rate offset compensation can be achieved. It is thus in particular advantageously possible to compensate for the phase position and the quadrature signal component of the analog signal in the detection circuit because the amplification range of the coupled interface amplifier is thereby efficiently utilized.

The advantages and designs that have been described in connection with the embodiments of the sensor system according to the present invention having an MEMS gyroscope can be used for the method for operating a sensor system having an MEMS gyroscope according to the present invention.

Exemplary embodiments of the present invention are illustrated in the figures and explained in more detail in the following description.

### BRIEF DESCRIPTION OF THE DRAWINGS

FIG. 1 shows a circuit diagram of a sensor system having an MEMS gyroscope according to the related art.

FIG. 2 is a very schematic representation of an equivalent circuit diagram to illustrate the principle of quadrature compensation according to an example embodiment of the present invention.

FIG. 3 is a schematic representation of a circuit diagram of the sensor system or of a part thereof according to an example embodiment of the present invention.

### DETAILED DESCRIPTION OF EXAMPLE EMBODIMENTS

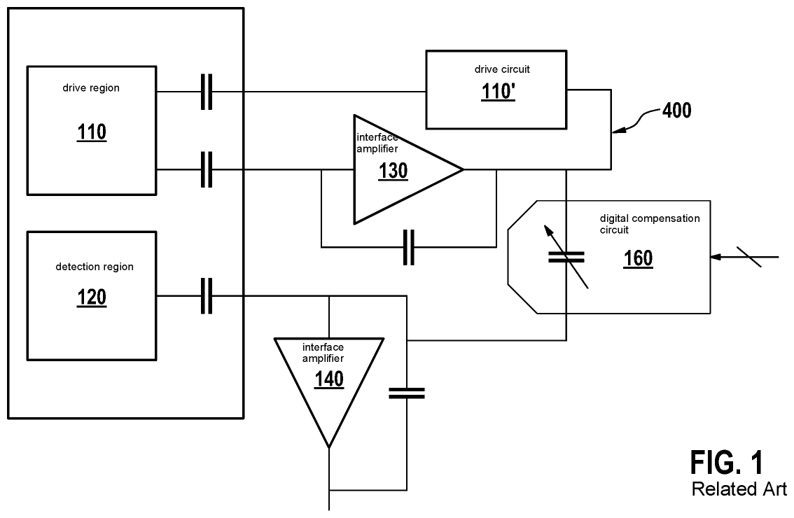

FIG. 1 shows a circuit diagram of a sensor system having an MEMS gyroscope according to the related art. The micromechanical structure of the MEMS gyroscope is excited to oscillate in a conventional manner and for this purpose comprises a drive region 110 that receives drive signals from a drive circuit 110′. Furthermore, the micromechanical structure of the MEMS gyroscope has a detection region 120 in a conventional manner, which detection region is coupled to a detection circuit. Also shown in FIG. 1 are two interface amplifiers 130 and 140 and a digital compensation circuit 160, as well as a reference sine signal 400. The compensation circuit 160 additionally comprises a (capacitive) digital-to-analog converter (not shown explicitly). Analog signals are prepared for further processing by means of the two interface amplifiers 130 and 140. By means of a compensation, an attempt is made to ensure that the quadrature signal component is largely corrected in the detected analog signal and only a rotation-rate signal component is maintained as far as possible.

The phase shift of the interface amplifier 140 associated with the detection region 120 depends on the setting of the quadrature compensation. However, the phase shift has to be known exactly in order to be able to apply a zero rate compensation, and is normally measured during the check (i.e., during the compensation at the end of the production process). Measuring the phase shift for each compensation setting would, however, require a large amount of additional test time and storage space.

Thus, in some conventional MEMS gyroscopes, compensation is carried out even during operation of the sensor, but this causes a phase shift unless the indicated considerable compensation effort has been carried out. In order to ensure efficient zero rate offset compensation for (digital) further processing, this phase shift must be corrected. However, as mentioned above, this would require a significant increase in the necessary test time or compensation time during production and in particular during testing or compensation or calibration of the sensor system and also require additional storage space, thus making it an inefficient procedure.

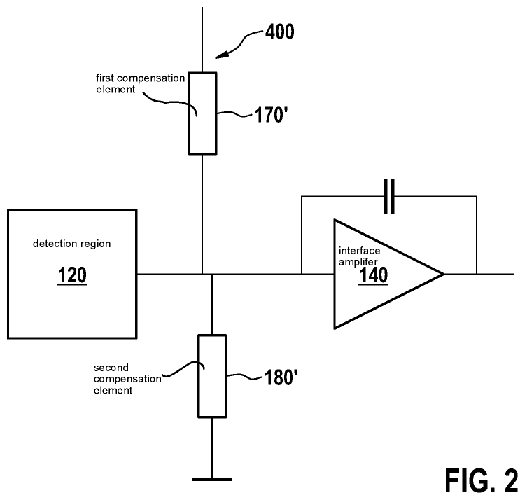

FIG. 2 shows an equivalent circuit diagram of a part of a sensor system having an MEMS gyroscope according to the present invention. A part of the detection circuit that is connected to the detection region 120 of the MEMS gyroscope is shown there.

Also shown are an associated interface amplifier 140 and a first compensation element 170′ and a second compensation element 180′, and the reference sine signal 400.

FIG. 2 shows basic features of the present invention: instead of measuring the phase delay of each compensation setting (or each QDAC setting or each setting of the quadrature digital-to-analog converter), the impedance Z_{quadrature} introduced by the first compensation element 170′ is realized (in particular realized by an additional capacitive array) and thus compensated for by an impedance opposite thereto by the second compensation element 180′, i.e., with the aforementioned impedance, but with a negative sign: −Z_{quadrature}. Such capacitive arrays are already used for analog-to-digital converters and for PGAs (programmable gain amplifiers). Owing to the compensation (by means of the second compensation element 180′) of the impedance introduced by the first compensation element 170′, the phase delay of the interface amplifier 140 associated with the detection region 120 is kept constant.

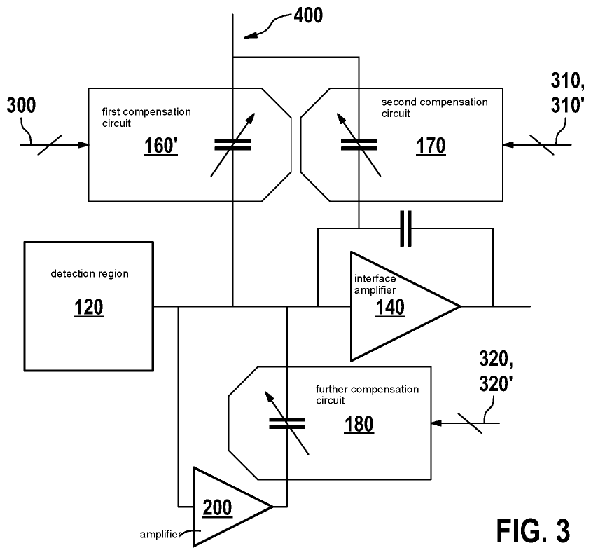

FIG. 3 schematically shows a circuit diagram of a part of the resonant sensor system or of the sensor system having an MEMS gyroscope according to an embodiment of the present invention.

In addition to the detection region 120 and the interface amplifier 140 associated therewith, a digital processing arrangement having a first compensation circuit 160′, a second compensation circuit 170, and a further compensation circuit 180, and an amplifier 200 and the reference sine signal 400 are shown. The first compensation circuit 160′ comprises a first digital-to-analog converter, the second compensation circuit 170 comprises a second digital-to-analog converter, and the further compensation circuit 180 comprises a further digital-to-analog converter. Because the quadrature signal component can vary greatly in the analog signal for different detection structures (i.e., between different MEMS gyroscopes), and is also—compared to the rotation-rate signal component—the dominant signal component, it is preferably provided according to the present invention that the first digital-to-analog converter has a substantially larger value range that can be covered or represented than the second and further digital-to-analog converters. This has the advantage that a lower circuit complexity can thereby be realized. In the second and further digital-to-analog converters (in the second and further compensation circuits 170, 180), it is then only necessary (due to the compensation of the main absolute value component of the quadrature signal component by the first compensation circuit 160′) to cover a significantly smaller dynamic range, so that the digital-to-analog conversion can take place more precisely, i.e., with a smaller value range that can be covered or represented. Furthermore, the possibility thus arises of maintaining the accuracy of the compensation of the quadrature signal component, even over the entire run time of the operation of the sensor system.

The quadrature signal component is thus compensated for with regard to its main absolute value component by means of the first compensation circuit 160′. For this purpose, the first compensation circuit 160′ applies a first digital signal 300 to the first digital-to-analog converter. The first digital-to-analog converter converts the first digital signal 300 to a first analog signal. The first analog signal compensates for the main absolute value component of the quadrature signal component of the analog signal, i.e., with respect to the main absolute value component of the quadrature signal component. During the production and calibration (or compensation) of the sensor system, the first digital signal 300 (trim code C) is ascertained and, during operation of the sensor system, the first digital signal 300 is (permanently) applied to the first digital-to-analog converter from the first compensation circuit 160′.

With regard to the further compensation of the quadrature signal component and the change in the phase position of the (entire) analog signal additionally triggered thereby, the second compensation circuit 170 applies a second digital signal 310 (trim code 0) to the second digital-to-analog converter, and the further compensation circuit 180 applies a further digital signal 320 (trim code 0) to the further digital-to-analog converter. The second digital-to-analog converter converts the second digital signal 310 to a second analog signal to further compensate for the quadrature signal component and the further digital-to-analog converter converts the further digital signal 320 to a further analog signal to carry out the phase position correction of the phase position of the analog signal, in particular by means of a capacitive array. This is necessary because a change in the phase position of the (entire) analog signal is triggered at least by the compensation of the further component (not yet compensated for by the compensation of the main absolute value component) of the quadrature signal component. The second digital signal 310 and the further digital signal 320 are therefore selected in each case—i.e., both during the compensation of the sensor system within the scope of production (in each case trim code 0) and during ongoing operation when a threshold value (in each case trim code X) is exceeded-such that at least the phase position of the second analog signal is inverted by the further analog signal. During the production and calibration (or compensation) of the sensor system, the second digital signal 310 and the further digital signal 320 are ascertained in the course of the further compensation of the quadrature signal component and the correction of the change in the phase position of the (entire) analog signal additionally triggered by this compensation, and are assigned to a phase position correction value. During operation, the phase position correction value is checked (quasi) continuously and is adapted by means of a second readjusted digital signal 310′ (trim code X) and a further readjusted digital signal 320′ (trim code X). This results in a lower compensation effort during production and calibration, and efficient use during operation of the sensor system.

1.-8. (canceled)

9. A resonant sensor system, comprising:
a drive circuit configured to generate an analog drive signal to drive an oscillatable seismic element of a MEMS gyroscope;
a detection circuit coupled to the drive circuit and the oscillatable seismic element, wherein the detection circuit is configured to detect an analog signal from a motion of the oscillatable element, wherein the analog signal includes an analog rotation-rate signal component and an analog quadrature signal component;
a digital processing arrangement having at least one digital-to-analog converter and a further digital-to-analog converter, the digital processing arrangement further including:
a compensation circuit coupled to the detection circuit and configured to detect the quadrature signal component and to apply a digital signal to the digital-to-analog converter to compensate for the quadrature signal component, wherein the digital-to-analog converter converts the digital signal to an analog compensation signal to compensate for the quadrature signal component, and
a further compensation circuit coupled to the detection circuit and configured to receive the digital signal from the compensation circuit and to apply a further digital signal to the further digital-to-analog converter to carry out a phase position correction of aphase position of the analog signal by the further digital-to-analog converter, thereby causing at least the phase position of the analog compensation signal to be inverted.

10. The sensor system according to claim 9, wherein:
the digital-to-analog converter includes a first digital-to-analog converter and a second digital-to-analog converter, wherein the compensation circuit includes a first compensation circuit and a second compensation circuit,
the first compensation circuit is coupled to the detection circuit and is configured to detect a main absolute value component of the quadrature signal component and to apply a first digital signal to the first digital-to-analog converter to at least partially compensate for the quadrature signal component, wherein the first digital-to-analog converter converts the first digital signal to a first analog signal to compensate for the main absolute value component of the quadrature signal component,
the second compensation circuit is coupled to the detection circuit and configured to detect a further component of the quadrature signal component and to apply a second digital signal to the second digital-to-analog converter to further compensate for the quadrature signal component, wherein the second digital-to-analog converter converts the second digital signal to a second analog signal to further compensate for the quadrature signal component, and
the further compensation circuit is configured to receive the second digital signal from the second compensation circuit and to apply the further digital signal to the further digital-to-analog converter to carry out a phase position correction of the phase position of the analog signal by the further digital-to-analog converter, thereby causing at least the phase position of the second analog signal to be inverted.

11. The sensor system according to claim 10, wherein the first digital-to-analog converter has a significantly larger value range that can be covered or represented than the second and the further digital-to-analog converters, the value range that can be covered or represented being at least twice as large than the second and the further digital-to-analog converters.

12. The sensor system according to claim 9, wherein the further digital-to-analog converter includes a structure including a plurality of coupled capacitive units.

13. The sensor system according to claim 9, wherein the detection circuit is coupled to an interface amplifier.

14. The sensor system according to claim 9, wherein the further digital-to-analog converter is coupled to an analog amplifier which carries out an amplification of up to twenty times.

15. A method for operating a resonant sensor system, the resonant sensor circuit including:
a drive circuit configured to generate an analog drive signal to drive an oscillatable seismic element of a MEMS gyroscope.
a detection circuit coupled to the drive circuit and the oscillatable seismic element, wherein the detection circuit detects an analog signal from a motion of the oscillatable element, wherein the analog signal includes an analog rotation-rate signal component and an analog quadrature signal component, and
a digital processing arrangement having at least one digital-to-analog converter and a further digital-to-analog converter, the digital processing arrangement additionally including a compensation circuit and a further compensation circuit, wherein the compensation circuit and the further compensation circuit are each coupled to the detection circuit,
the method comprising the following steps:
in a compensation step:
detecting, by the compensation circuit, the quadrature signal component and applying, by the compensation circuit, a digital signal to the digital-to-analog converter to compensate for the quadrature signal component, wherein the digital-to-analog converter converts the digital signal to an analog signal to compensate for the quadrature signal component, and
receiving, by the further compensation circuit, the digital signal from the compensation circuit and applying, by the further compensation circuit, a further digital signal to the further digital-to-analog converter to carry out a phase position correction of a phase position of the analog signal by the further digital-to-analog converter, thereby causing at least the phase position of the analog compensation signal to be inverted.

16. The method for operating the resonant sensor system according to claim 15, wherein the digital-to-analog converter includes a first digital-to-analog converter and a second digital-to-analog converter, the compensation circuit includes a first compensation circuit and a second compensation circuit, and wherein the first, second, and the further compensation circuit are each coupled to the detection circuit, wherein:
in a first method step, the first compensation circuit detects a main absolute value component of the quadrature signal component and applies a first digital signal to the first digital-to-analog converter to at least partially compensate for the quadrature signal component, wherein the first digital-to-analog converter converts the first digital signal to a first analog signal to compensate for the main absolute value component of the quadrature signal component,
in a second method step, the compensation step is carried out in such a way that the second compensation circuit, in addition to the main absolute value component of the quadrature signal component, detects a further component of the quadrature signal component and applies a second digital signal to the second digital-to-analog converter to further compensate for the quadrature signal component, wherein the second digital-to-analog converter converts the second digital signal to a second analog signal to further compensate for the quadrature signal component, and the further compensation circuit receives the second digital signal from the second compensation circuit and applies the further digital signal to the further digital-to-analog converter to carry out the phase position correction of the phase position of the analog signal by the further digital-to-analog converter, thereby causing at least the phase position of the second analog signal to be inverted.
